(19) United States
(12) Patent Application Publication
(10) Pub. No.: US 2016/0329881 A1
(43) Pub. Date: Nov. 10, 2016

(54) AMPLIFYING CIRCUIT

(71) Applicants: KABUSHIKI KAISHA TOSHIBA, Minato-ku (JP); Tokyo University of Science Foundation, Shinjuku-ku (JP)

(72) Inventors: Junya MATSUNO, Kawasaki (JP); Masanori FURUTA, Odawara (JP); Tetsuro ITAKURA, Nerima (JP); Akira HYOGO, Shinjuku (JP); Tatsuji MATSUURA, Shinjuku (JP); Takuya HARA, Shinjuku (JP)

(73) Assignees: KABUSHIKI KAISHA TOSHIBA, Minato-ku (JP); Tokyo University of Science Foundation, Shinjuku-ku (JP)

(21) Appl. No.: 15/061,562

(22) Filed: Mar. 4, 2016

(30) Foreign Application Priority Data
May 7, 2015 (JP) 2015-095138

(51) Int. Cl. H03K 3/0233; H03M 1/12; H04B 1/04; G11C 27/02

(52) U.S. Cl. CPC H03K 3/0233; G11C 27/026; H03M 1/12; H04B 1/0458; H04B 2001/045

(57) ABSTRACT

An amplifying circuit according to an embodiment includes a sample and hold circuit, an operational amplifier, a feedback capacitance, and a level shift circuit. The sample and hold circuit includes a sampling capacitance to sample an analog input signal in a sampling phase. The operational amplifier amplifies and outputs the analog input signal held by the sampling capacitance in the amplifying phase. The feedback capacitance is connected between the input terminal of the operational amplifier and the analog output terminal. The level shift circuit includes a level shift capacitance to sample the analog input signal in the sampling phase. A plurality of level shift capacitances is provided and connected in cascade between the output terminal of the operational amplifier and the analog output terminal.

### CROSS REFERENCE TO RELATED APPLICATION(S)

This application is based upon and claims the benefit of priority from the prior Japanese Patent Application No. 2015-095138, filed on May 7, 2015, the entire contents of which are incorporated herein by reference.

### FIELD

Embodiments described herein relate generally to an amplifying circuit.

### BACKGROUND

An amplifying circuit with an operational amplifier having improved gain by using a correlated level shift technique (CLS) has been known. Such an amplifying circuit operates in three phases including a sampling phase to sample an input signal, a detection phase to detect an output error, and a level shift phase to level shift an output signal. Amplifying accuracy is thereby improved, but a problem of decreasing throughput has occurred.

To increase the operation speed of the amplifying circuit, therefore, an amplifying circuit in which the level shift phase is omitted has been proposed. The level shift phase is omitted by sampling an input signal by a level shift capacitance in the amplifying circuit during the sampling phase. The amplifying circuit, however, can only be applied to a buffer circuit with a gain 1. Therefore, arbitrarily setting the gain or being applied to a multiplying digital-to-analog converter (MDAC) has not been possible for the amplifying circuit in the past.

### BRIEF DESCRIPTION OF THE DRAWINGS

FIG. 1 illustrates an amplifying circuit according to a first embodiment;

FIG. 2 is an explanatory diagram to explain the structure of a level shift circuit of FIG. 1;

FIG. 3 illustrates a variation of the amplifying circuit of FIG. 1;

FIG. 4 illustrates a variation of the amplifying circuit of FIG. 1;

FIG. 5 illustrates a variation of the amplifying circuit of FIG. 1;

FIG. 6 illustrates an amplifying circuit according to a second embodiment;

FIG. 7 illustrates an amplifying circuit according to a third embodiment;

FIG. 8 is an explanatory diagram to explain an operation of the amplifying circuit of FIG. 7;

FIG. 9 is an explanatory diagram to explain the operation of the amplifying circuit of FIG. 7;

FIG. 10 illustrates a variation of the amplifying circuit of FIG. 7;

FIG. 11 illustrates a variation of the amplifying circuit of FIG. 10;

FIG. 12 illustrates a variation of the amplifying circuit of FIG. 11;

FIG. 13 illustrates a variation of the amplifying circuit of FIG. 7;

FIG. 14 is an explanatory diagram to explain the operation of the amplifying circuit of FIG. 13;

FIG. 15 is an explanatory diagram to explain the operation of the amplifying circuit of FIG. 13;

FIG. 16 illustrates a variation of the amplifying circuit of FIG. 13;

FIG. 17 is a functional block diagram of an A-D converter according to a fourth embodiment; and

FIG. 18 illustrates the hardware structure of a radio communication apparatus according to a fifth embodiment.

### DETAILED DESCRIPTION

Embodiments will now be explained with reference to the accompanying drawings. The present invention is not limited to the embodiments.

An amplifying circuit according to an embodiment includes an analog input terminal, an analog output terminal, a sample and hold circuit, an operational amplifier, a feedback capacitance, and a level shift circuit. The analog input terminal receives an analog input signal. The analog output terminal outputs an analog output signal. The sample and hold circuit includes a sampling capacitance and a plurality of switches that switch between a sampling phase and an amplifying phase. The sampling capacitance samples the analog input signal in the sampling phase and holds it in the amplifying phase. The operational amplifier includes an input terminal, which is connected to the sample and hold circuit, and an output terminal. The operational amplifier amplifies and outputs the analog input signal held in the sampling capacitance in the amplifying phase. The feedback capacitance is connected between the input terminal of the operational amplifier and the analog output terminal. The level shift circuit includes a level shift capacitance and a plurality of switches that switch between the sampling phase and the amplifying phase. The level shift capacitance samples the analog input signal in the sampling phase and holds it in the amplifying phase. A plurality of level shift capacitances is provided and connected in cascade between the output terminal of the operational amplifier and the analog output terminal.

### First Embodiment

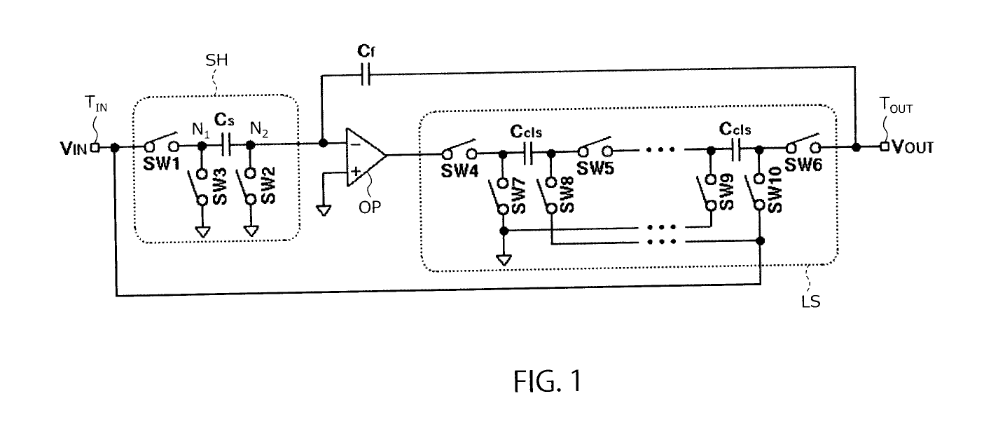

An amplifying circuit according to a first embodiment will be described by referring to FIGS. 1 to 5. FIG. 1 illustrates an amplifying circuit according to the present embodiment. The amplifying circuit described below has a design gain X, where X is an arbitrary integer equal to or larger than 2.

As illustrated in FIG. 1, the amplifying circuit according to the present embodiment includes an analog input terminal T_{IN}, an analog output terminal T_{OUT}, a sample and hold circuit SH, an operational amplifier OP, a feedback capacitance Cf, and a level shift circuit LS.

An analog input signal V_{IN} (referred to as an input signal V_{IN} hereinafter) is input to the analog input terminal T_{IN} (referred to as the input terminal T_{IN} hereinafter).

An analog output signal V_{OUT} (referred to as an output signal V_{OUT} hereinafter) is output from the analog output terminal T_{OUT} (referred to as the output terminal T_{OUT} hereinafter). The output signal V_{OUT} is a signal obtained by amplifying the input signal V_{IN} by gain X in the amplifying circuit.

The sample and hold circuit SH is a switched capacitor circuit connected between the input terminal T_{IN} and an inverted input terminal of the operational amplifier OP. The sample and hold circuit operates in two phases including the sampling phase and the amplifying phase. The sample and hold circuit SH includes a sampling capacitance Cs and three switches SW1 to SW3.

The sampling capacitance Cs has its one end connected to a node N₁ and the other end connected to a node N₂. The node N₁ is a connection point between the sampling capacitance Cs and the switches SW1, SW3. The node N₂ is a connection point among the sampling capacitance Cs, the switch SW2, the feedback capacitance Cf, and the input terminal of the operational amplifier. The sampling capacitance Cs has a capacitance value Cs. The sampling capacitance Cs samples the input signal V_{IN} in the sampling phase. The sampling capacitance Cs holds the sampled input signal V_{IN} in the amplifying phase.

The switch SW1 has its one end connected to the input terminal T_{IN} and the other end connected to the node N₁. The switch SW2 has its one end connected to the node N₂ and the other end connected to the ground line. Being connected to the ground line will be referred to as being grounded hereinafter. The switch SW3 has its one end connected to the node N₁ and the other end grounded.

In the sampling phase, the switches SW1, SW2 are turned on and the switch SW3 is turned off. Accordingly, the input signal V_{IN} is sampled by the sampling capacitance Cs.

In the amplifying phase, the switches SW1, SW2 are turned off and the switch SW3 is turned on. Accordingly, the input signal V_{IN}, which has been sampled by the sampling capacitance Cs, is held.

The operational amplifier OP amplifies the input signal V_{IN}, which has been held by the sampling capacitance Cs, and outputs the amplified input signal from the output terminal. The operational amplifier OP includes an inverted input terminal, a non-inverted input terminal, and an output terminal. The inverted input terminal is connected to the node N₂. The non-inverted terminal is grounded. The output terminal is connected to the level shift circuit LS.

The feedback capacitance Cf has its one end connected to the node N₂ and the other end thereof connected to the output terminal T_{OUT}. That is, the feedback capacitance Cf is connected between the inverted input terminal of the operational amplifier OP and the output terminal T_{OUT}. The feedback capacitance Cf, therefore, forms a negative feedback circuit of the operational amplifier OP. The feedback capacitance Cf has a capacitance value Cf. Cs is set to an X times multiple of Cf (Cs:Cf=X:1).

The level shift circuit LS is a switched capacitor circuit connected between the output terminal of the operational amplifier OP and the output terminal T_{OUT}. The level shift circuit LS operates in two phases including the sampling phase and the amplifying phase. The level shift circuit LS includes X level shift capacitances Ccls and a plurality of switches.

The X capacitances Ccls are connected in cascade between the output terminal of the operational amplifier OP and the output terminal T_{OUT} via the switches. In the example of FIG. 1, the level shift capacitances Ccls and the switches are connected in the order of the output terminal of the operational amplifier OP, a switch SW4, a first level shift capacitance Ccls, a switch SW5, to the Xth level shift capacitance Ccls, a switch SW6, and the output terminal T_{OUT}.

Each level shift capacitance Ccls samples the input signal V_{IN} in the sampling phase. Each level shift capacitance Ccls then holds the sampled input signal V_{IN} in the amplifying phase. Each level shift capacitance Ccls has a capacitance value Ccls. Individual Ccls may be the same or may be different from each other.

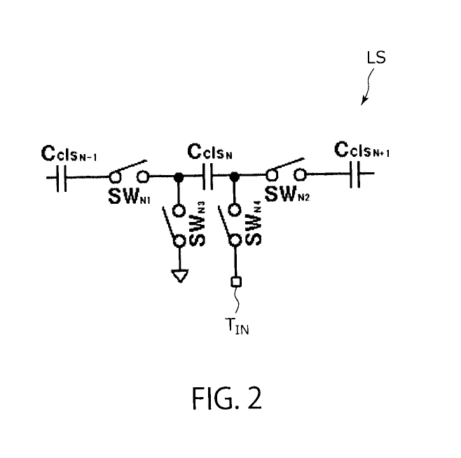

The level shift capacitances Ccls and four switches form a switched capacitor circuit. The Nth level shift capacitance Ccls is expressed as a level shift capacitance Ccls_{N}. FIG. 2 illustrates an Nth switched capacitor circuit formed by the level shift capacitance Ccls_{N}.

As illustrated in FIG. 2, the Nth switched capacitor circuit includes the level shift capacitance Ccls_{N} and four switches SW_{N1} to SW_{N4}. The switch SW_{N1} has its one end connected to the other end of a level shift capacitance Ccls_{N-1} and the other end connected to one end of the level shift capacitance Ccls_{N}. The switch SW_{N2} has its one end connected to the other end of the level shift capacitance Ccls_{N} and the other end connected to one end of a level shift capacitance Ccls_{N+1}. The switch SW_{N3} has its one end connected to the one end of the level shift capacitance Ccls_{N} and the other end grounded. The switch SW_{N4} has its one end connected to the other end of the level shift capacitance Ccls_{N} and the other end connected to the input terminal T_{IN}.

In the sampling phase, the switches SW_{N1}, SW_{N2} are turned off and the switches SW_{N3}, SW_{N4} are turned on. Accordingly, the input signal V_{IN} is sampled by the sampling capacitance Ccls_{N}.

In the amplifying phase, the switches SW_{N1}, SW_{N2} are turned on and the switches SW_{N3}, SW_{N4} are turned off. Accordingly, the input signal V_{IN}, which has been sampled by the sampling capacitance Ccls_{N}, is held.

For example, in the example of FIG. 1, the first switched capacitor circuit includes the first level shift capacitance Ccls, the switch SW4 (switch SW_{N1}), the switch SW5 (switch SW_{N2}), the switch SW7 (switch SW_{N3}), and the switch SW8 (switch SW_{N4}).

The Xth switched capacitor circuit includes the Xth level shift capacitance Ccls, the switch which is not illustrated (switch SW_{N1}), the switch SW6 (switch SW_{N2}), the switch SW9 (switch SW_{N3}), and the switch SW10 (switch SW_{N4}).

As can be seen from FIG. 1, the switch SW_{N1} (switch SW4) of the first switched capacitor circuit has its one end connected to the output terminal of the operational amplifier OP. The switch SW_{N2} (switch SW6) of the Xth switched capacitor circuit has the other end connected to the output terminal T_{OUT}.

Next, the operation of the amplifying circuit of FIG. 1 will be described.

In the sampling phase, the switches SW1, SW2 are turned on and the switch SW3 is turned off. Accordingly, the input signal V_{IN} is sampled by the sampling capacitance Cs.

In the sampling phase, the switches SW_{N3}, SW_{N4} are turned on and the switches SW_{N1} and SW_{N2} are turned off. Accordingly, the input signal V_{IN} is sampled by the X sampling capacitances Ccls.

In the amplifying phase, the switches SW1, SW2 are turned off and the switch SW3 is turned on. Accordingly, one end of the sampling capacitance Cs is grounded, and the other end thereof is connected to the inverted input terminal of the operational amplifier OP. The operational amplifier OP operates such that the voltage at the inverted input terminal becomes equal to the voltage at the non-inverted input terminal. Thus, the electric charge of the sampling capacitance Cs is transferred to the feedback capacitance Cf.

When the voltage at the inverted input terminal perfectly matches the ground voltage, the entire electric charge of the sampling capacitance Cs is transferred to the feedback capacitance Cf. Since Cs:Cf=X:1, the output signal is V_{OUT}=X×V_{IN}.

Actually, however, the gain of the operational amplifier OP has a limit, the voltage at the inverted input terminal does not perfectly match the ground voltage, and an error is generated. As a result, an amplifying error α is generated in the output signal (V_{OUT}=X×V_{IN}+α).

Meanwhile, in the amplifying phase, the switches SW_{N3}, SW_{N4} are turned off and the switches SW_{N1}, SW_{N2} are turned on. Accordingly, the input signal V_{IN} is held by the X level shift capacitances Ccls. Since the X level shift capacitances Ccls are connected in cascade between the output terminal of the operational amplifier OP and the output terminal T_{OUT}, the voltage at the output terminal T_{OUT} (analog output signal V_{OUT}) becomes a level-shifted voltage obtained by level shifting the voltage at the output terminal of the operational amplifier OP by X×V_{IN}. When V_{OUT}=X×V_{IN}+α, the voltage at the output terminal of the operational amplifier OP is α(=V_{OUT}−X×V_{IN}).

In the amplifying circuit according to the present embodiment, the negative feedback is applied such that the voltage a at the output terminal of the operational amplifier OP is 0. This minimizes an error between the voltage at the negative input terminal and the ground voltage, and decreases the amplifying error α.

As described above, the amplifying circuit according to the present embodiment can improve the gain of the operational amplifier OP equivalently by the level shift circuit LS. Therefore, the output signal V_{OUT} comes close to X×V_{IN} t, when compared to the amplifying circuit that does not include the level shift circuit LS, and amplifying accuracy is improved.

In addition, the amplifying circuit according to the present embodiment can amplify the input signal V_{IN} in two phases of the sampling phase and the amplifying phase, high speed operation is possible compared to the amplifying circuit that operates in three phases.

Further, when the number of level shift capacitances Ccls to be connected in cascade is adjusted, the amplifying circuit of the present embodiment can realize an amplifying circuit having an arbitrary gain X.

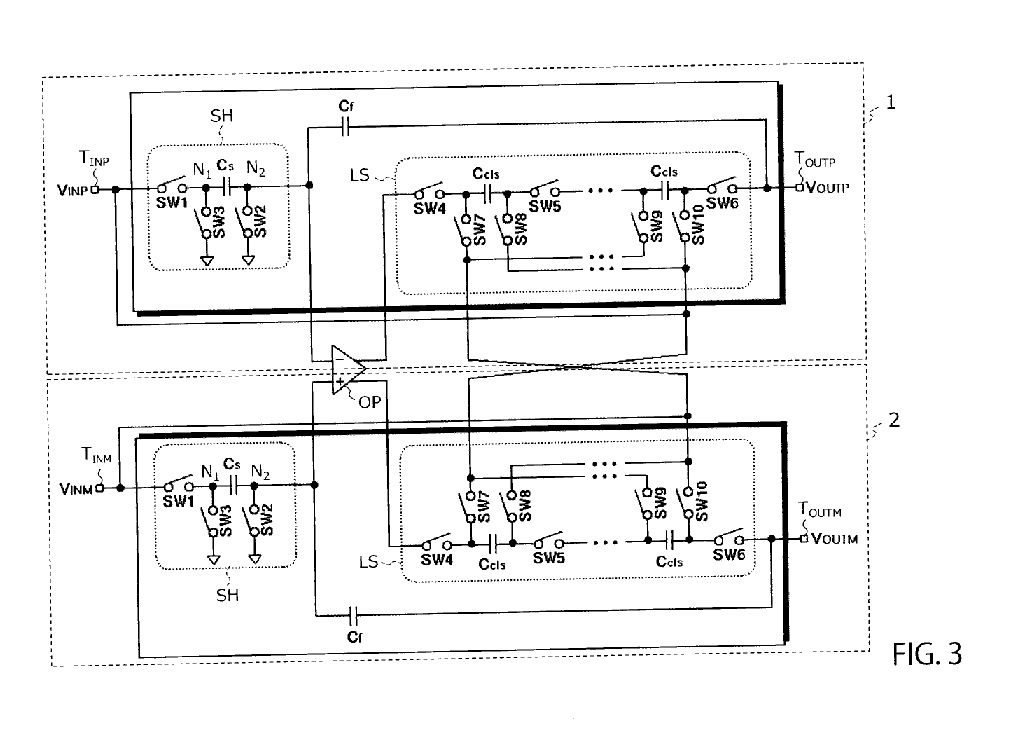

FIG. 3 illustrates a differential amplifying circuit formed by the amplifying circuit of FIG. 1 having a differential structure. The amplifying circuit of FIG. 3 receives differential input signals V_{INP}, V_{INM} and outputs differential output signals V_{OUTP}, V_{OUTM}. As illustrated in FIG. 3, the amplifying circuit includes a first amplifying circuit 1 and a second amplifying circuit 2.

The first amplifying circuit 1 includes an input terminal T_{INP}, an analog output terminal T_{OUTP}, a sample and hold circuit SH, an operational amplifier OP, a feedback capacitance Cf, and a level shift circuit LS.

The second amplifying circuit 2 includes an input terminal T_{INM}, an analog output terminal T_{OUTM}, a sample and hold circuit SH, the operational amplifier OP, a feedback capacitance Cf, and a level shift circuit LS.

The first and second amplifying circuits 1, 2 are configured in the same manner as the amplifying circuit of FIG. 1, except for the operational amplifier OP and the level shift circuit LS. The operational amplifier OP and the level shift circuit LS of the amplifying circuit of FIG. 3 will be described below.

The operational amplifier OP is used by both the first and second amplifying circuits 1, 2. The operational amplifier OP includes an inverted input terminal, a non-inverted input terminal, an inverted output terminal, and a non-inverted output terminal. The inverted input terminal is connected to the node N₂ of the sample and hold circuit SH of the first amplifying circuit 1. The non-inverted input terminal is connected to the node N₂ of the sample and hold circuit SH of the second amplifying circuit 2. The inverted output terminal is connected to one end of the switch SW4 of the level shift circuit LS of the first amplifying circuit 1. The non-inverted output terminal is connected to one end of the switch SW4 of the level shift circuit LS of the second amplifying circuit 2.

The other end of the switch SW7 of the level shift circuit LS of the first amplifying circuit 1 is connected to the input terminal T_{INM} of the second amplifying circuit 2. The other end of the switch SW7 of the level shift circuit LS of the second amplifying circuit 2 is connected to the input terminal T_{INP} of the first amplifying circuit 1. The first and second amplifying circuits 1, 2 each includes X/2 level shift capacitances Ccls in the level shift circuit LS. Other portions of the structure of the level shift circuit LS are similar to those of FIG. 1.

With this structure, the amplifying circuit of FIG. 3 enables highly accurate and high speed amplification of the difference between the input signals V_{INP} and V_{INM}, and provides a differential output.

In the amplifying circuit of FIG. 3, the difference between the input signals V_{INP} and V_{INM} is sampled by each level shift capacitance Ccls. Since the input signals V_{INP}, V_{INM} are reversed phase voltages, a voltage twice as large as the voltage sampled by the level shift capacitance Ccls of FIG. 1 is sampled by each level shift capacitance Ccls. As a result of this, the X/2 level shift capacitances Ccls are provided in each level shift circuit LS, as mentioned above. Since the number of level shift capacitances Ccls is thus reduced by half in the amplifying circuit of FIG. 3, the circuit area can be decreased. In addition, power consumption of the circuit necessary to drive the level shift capacitances Ccls can be reduced.

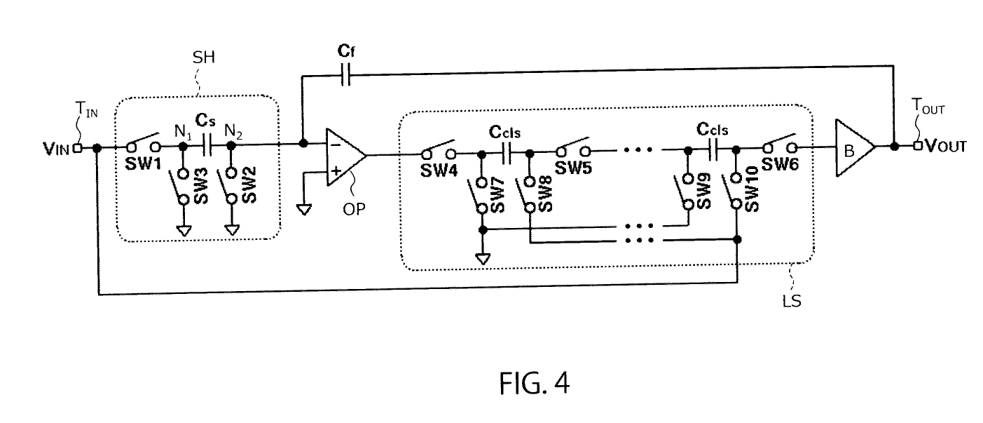

FIG. 4 illustrates a variation of the amplifying circuit of FIG. 1. The amplifying circuit of FIG. 4 further includes a buffer circuit B. Other portions of the structure of the amplifying circuit of FIG. 4 are similar to those of FIG. 1.

The buffer circuit B is connected between the level shift circuit LS and the analog output terminal T_{OUT}. Specifically, the input terminal of the buffer circuit B is connected to the other end of the Xth switch SW_{N2} (switch SW6) of the switched capacitor circuit of the level shift circuit LS. The output terminal of the buffer circuit B is connected to the analog output terminal T_{OUT}. The buffer circuit B has high input impedance and low output impedance.

With this structure, the amplifying circuit of FIG. 4 prevents re-distribution of the electric charge in the amplifying phase between the level shift capacitance Ccls and load capacitance connected to the poststage of the amplifying circuit. If the re-distribution of the electric charge occurs between the level shift capacitance Ccls and the load capacitance in the amplifying phase, the voltage held by the level shift capacitance Ccls is changed. This leads to an amplifying error. The amplifying circuit of FIG. 4, however, can prevent the re-distribution of the electric charge to further improve the amplifying accuracy.

In addition, the flow of the electric charge into the level shift capacitance Ccls is suppressed in the amplifying phase, the capacitance value of the level shift capacitance Ccls can be decreased. Accordingly, the decrease of the circuit area and the reduction of the power consumption of the circuit to drive the level shift capacitance Ccls are possible.

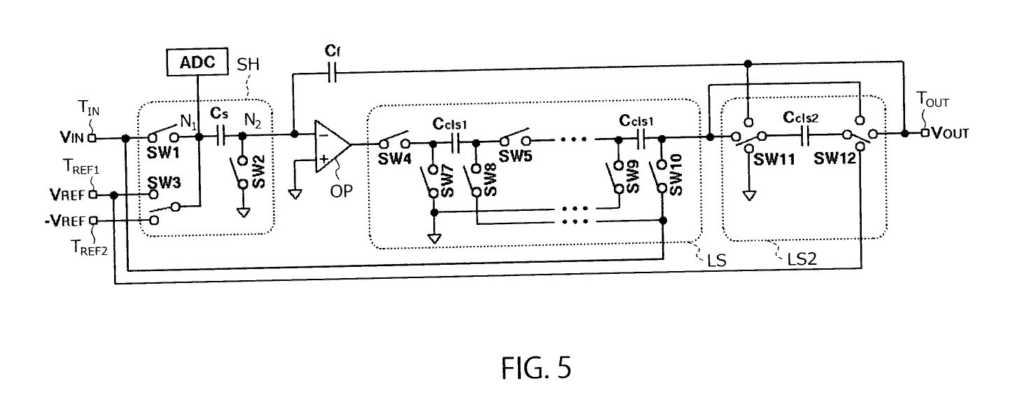

FIG. 5 illustrates a variation of the amplifying circuit of FIG. 1. The amplifying circuit of FIG. 5 includes a positive reference signal input terminal T_{REF1}, a negative reference signal input terminal T_{REF2}, an A-D converter (ADC), and a second level shift circuit LS2. The switch SW3 switches between the positive reference signal input terminal T_{REF1} and the negative reference signal input terminal T_{REF2}. The level shift capacitance Ccls1 of FIG. 5 corresponds to the level shift capacitance Ccls of FIG. 1. Other portions of the structure of the amplifying circuit of FIG. 5 are similar to those of FIG. 1.

A positive reference signal is input to the positive reference signal input terminal T_{REF1} (referred to as the input terminal T_{REF1} hereinafter). The positive reference signal is represented by V_{REF}. A negative reference signal is input to the negative reference signal input terminal T_{REF2} (referred to as the input terminal T_{REF2} hereinafter). The negative reference signal is represented by −V_{REF}. Both of the input terminals T_{REF1}, T_{REF2} can be connected to the other end of the switch SW3.

The input terminal of the A-D converter is connected to the node N₁. The A-D converter operates in synchronism with the sampling phase and the amplifying phase of the amplifying circuit. In the amplifying phase, the A-D converter compares the input signal V_{IN} having been sampled at the end of the sampling phase (i.e., the input signal V_{IN} held by the sampling capacitance Cs in the amplifying phase) with a common-mode voltage V_{COM} of the input signal V_{IN}, and outputs a binary signal according to a comparison result. The A-D converter herein outputs High when V_{IN}>V_{COM} and outputs Low when V_{IN}<V_{COM}. Switching of the switches SW3, SW11, and SW12 in the amplifying phase is controlled by the output signal of the A-D converter. The A-D converter may be formed by a comparator.

The level shift circuit LS2 (second level shift circuit) is a switched capacitor circuit connected between the level shift circuit LS and the output terminal T_{OUT}. The level shift circuit LS operates in two phases including the sampling phase and the amplifying phase. The level shift circuit LS2 includes the level shift capacitance Ccls2 and the switches SW11, SW12.

The level shift capacitance Ccls2 samples the positive reference signal V_{REF} in the sampling phase and holds it in the amplifying phase. The level shift capacitance Ccls2 has its one end connected to one end of the switch SW11 and the other end connected to one end of the switch SW12.

The switch SW11 has its one end connected to one end of the level shift capacitance Ccls2. The other end of the switch SW11 is switchable among the output terminal T_{OUT}, the other end of the Xth level shift capacitance Ccls1 of the level shift circuit LS, and the ground line.

The switch SW12 has its one end connected to the other end of the level shift capacitance Ccls2. The other end of the switch SW12 is switchable among the other end of the Xth level shift capacitance Ccls1 of the level shift circuit LS, the output terminal T_{OUT}, and the input terminal T_{REF1}.

The switch SW3 is turned off in the sampling phase. Accordingly, the input signal V_{IN} is sampled by the sampling capacitance Cs. The other end of the switch SW11 is grounded, and the other end of the switch SW12 is connected to the input terminal T_{REF1}. Accordingly, the positive reference signal V_{REF} is sampled by the level shift capacitance Ccls2.

In the amplifying phase, when the A-D converter outputs High, the other end of the switch SW3 is connected to the input terminal T_{REF2}, the other end of the switch SW11 is connected to the output terminal T_{OUT}, and the other end of the switch SW12 is connected to the other end of the Xth level shift capacitance Ccls1 of the level shift circuit LS. Accordingly, the output signal V_{OUT} becomes a signal formed by adding the reference signal V_{REF} to the voltage whose level has been shifted by the level shift circuit LS.

In the amplifying phase, when the A-D converter outputs Low, the other end of the switch SW3 is connected to the input terminal T_{REF1}, the other end of the switch SW11 is connected to the other end of the Xth level shift capacitance Ccls1 of the level shift circuit LS, and the other end of the switch SW12 is connected to the output terminal T_{OUT}. Accordingly, the output signal V_{OUT} becomes a signal formed by subtracting the reference signal V_{REF} from the voltage whose level has been shifted by the level shift circuit LS.

With this structure, the amplifying circuit of FIG. 5 can add/subtract the reference signal, as well as the amplification of the input signal V_{IN}. The amplifying circuit of FIG. 5 can therefore be used as a residual amplifying circuit, such as a multiplying digital-to-analog converter (MDAC).

### Second Embodiment

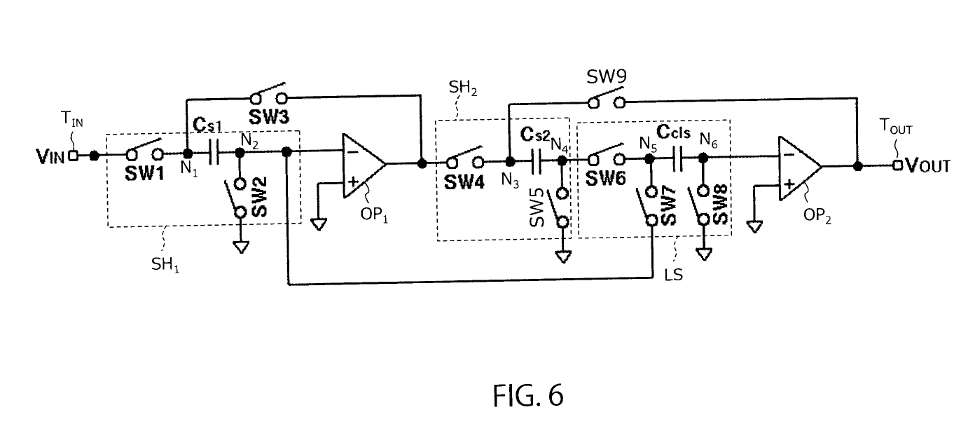

An amplifying circuit according to a second embodiment will be described by referring to FIG. 6. FIG. 6 illustrates an amplifying circuit according to the present embodiment. The amplifying circuit according to the present embodiment is an amplifying circuit having a gain 1, i.e., a buffer circuit.

As illustrated in FIG. 6, the amplifying circuit according to the present embodiment includes an analog input terminal T_{IN}, an analog output terminal T_{OUT}, a sample and hold circuit SH₁, an operational amplifier OP₁, a switch SW3, a sample and hold circuit SH₂, a level shift circuit LS, an operational amplifier OP₂, and a switch SW9.

An analog input signal V_{IN} (referred to as an input signal V_{IN} hereinafter) is input to the analog input terminal T_{IN} (referred to as the input terminal T_{IN} hereinafter).

An analog output signal V_{OUT} (referred to as an output signal V_{OUT} hereinafter) is output from the analog output terminal T_{OUT} (referred to as the output terminal T_{OUT} hereinafter). The output signal V_{OUT} is a signal obtained by amplifying the input signal V_{IN} by the gain 1 in the amplifying circuit.

The sample and hold circuit SH₁ (first sample and hold circuit) is a switched capacitor circuit connected between the input terminal T_{IN} and the inverted input terminal of the operational amplifier OP₁. The sample and hold circuit SH₁ operates in two phases including a first phase and a second phase. The sample and hold circuit SH₁ includes a sampling capacitance Cs₁ and two switches SW1, SW2.

The sampling capacitance Cs₁ (first sampling capacitance) has its one end connected to a node N₁ and the other end connected to a node N₂. The node N₁ is a connection point between the sampling capacitance Cs₁ and the switches SW1, SW3. The node N₂ is a connection point among the sampling capacitance Cs₁, the switches SW2, SW7, and the input terminal of the operational amplifier OP₁. The sampling capacitance Cs₁ has a capacitance value Cs₁. The sampling capacitance Cs₁ samples the input signal V_{IN} in the first phase. The sampling capacitance Cs₁ holds the sampled input signal V_{IN} in the second phase.

The switch SW1 has its one end connected to the input terminal T_{IN} and the other end connected to the node N₁. The switch SW2 has its one end connected to the node N₂ and the other end grounded.

In the first phase, the switches SW1, SW2 are turned on, and the input signal V_{IN} is sampled by the sampling capacitance Cs₁.

In the second phase, the switches SW1, SW2 are turned off, and the input signal V_{IN}, which has been sampled by the sampling capacitance Cs₁, is held.

The operational amplifier OP₁ (first operational amplifier) outputs the input signal V_{IN} held by the sampling capacitance Cs₁ from the output terminal. The operational amplifier OP₁ includes the inverted input terminal, the non-inverted input terminal, and the output terminal. The inverted input terminal is connected to the node N₂. The non-inverted terminal is grounded. The output terminal is connected to the sample and hold circuit SH₂. The operational amplifier OP₁ has a gain A₁.

The switch SW3 (first switch) has its one end connected to the node N₁ and the other end connected to the output terminal of the operational amplifier OP₁. That is, the switch SW3 is connected between one end of the sampling capacitance Cs₁ and the output terminal of the operational amplifier OP₁. The switch SW3 is turned off in the first phase. The switch SW3 is turned on in the second phase.

The sample and hold circuit SH₂ (second sample and hold circuit) is a switched capacitor circuit connected between the output terminal of the operational amplifier OP₁ and the level shift circuit LS. The sample and hold circuit SH₂ operates in two phases including a first phase and a second phase. The sample and hold circuit SH₂ includes a sampling capacitance Cs₂ and two switches SW4, SW5.

The sampling capacitance Cs₂ (second sampling capacitance) has its one end connected to the node N₃ and the other end connected to the node N₄. The node N₃ is a connection point between the sampling capacitance Cs₂ and the switches SW4, SW9. The node N₄ is a connection point between the sampling capacitance Cs₂ and the switches SW5, SW6. The sampling capacitance Cs₂ has a capacitance value Cs₂. The sampling capacitance Cs₂ samples the output signal of the operational amplifier OP₁ in the second phase. The sampling capacitance Cs₂ holds the sampled output signal of the operational amplifier OP₁ in the first phase.

The switch SW4 has its one end connected to the output terminal of the operational amplifier OP₁ and the other end connected to the node N₃. The switch SW4 has its one end connected to the node N₄ and the other end grounded.

In the second phase, the switches SW4, SW5 are turned on, and the output signal of the operational amplifier OP₁ is sampled by the sampling capacitance Cs₂.

In the first phase, the switches SW4, SW5 are turned off, and the sampled output signal of the operational amplifier OP₁, which has been sampled by the sampling capacitance Cs₂, is held.

The level shift circuit LS is a switched capacitor circuit connected between the sample and hold circuit SH2 and the inverted input terminal of the operational amplifier OP₂. The level shift circuit LS operates in two phases including the first phase and the second phase. The level shift circuit LS includes the level shift capacitance Ccls and three switches SW6 to SW8.

The level shift capacitance Ccls has its one end connected to the node N₅ and the other end connected to the node N₆. The node N₅ is a connection point between the level shift capacitance Ccls and the switches SW6, SW7. The node N₆ is a connection point among the level shift capacitance Ccls, the switch SW8, and the input terminal of the operational amplifier OP₂. The level shift capacitance Ccls has a capacitance value Ccls. In the second phase, the level shift capacitance Ccls samples a voltage (signal) of the inverted input terminal of the operational amplifier OP₁. In the first phase, the level shift capacitance Ccls holds the sampled voltage of the inverted input terminal of the operational amplifier OP₁.

The switch SW6 has its one end connected to the node N₄ and the other end connected to the node N₅. The switch SW7 has its one end connected to the node N₅ and the other end connected to the inverted input terminal of the operational amplifier OP₁. The switch SW8 has its one end connected to the node N₆ and the other end grounded.

In the second phase, the switches SW7, SW8 are turned on and the switch SW6 is turned off. Accordingly, the voltage of the inverted input terminal of the operational amplifier OP₁ is sampled by the level shift capacitance Ccls.

In the first phase, the switches SW7, SW8 are turned off and the switch SW6 is turned on. Accordingly, the voltage, which has been sampled by the level shift capacitance Ccls, of the inverted input terminal of the operational amplifier OP₁ is held.

The operational amplifier OP₂ (second operational amplifier) outputs the signal held by the sampling capacitance Cs₂ sand the level shift capacitance Ccls from the output terminal. The operational amplifier OP₂ includes an inverted input terminal, a non-inverted input terminal, and an output terminal. The inverted input terminal is connected to the node N₆. The non-inverted terminal is grounded. The output terminal is connected to the node N₃. The operational amplifier OP₂ has a gain A₂.

The switch SW9 (second switch) has its one end connected to the node N₃ and the other end connected to the output terminal of the operational amplifier OP₂. That is, the switch SW9 is connected between one end of the sampling capacitance Cs₂ and the output terminal of the operational amplifier OP₂. The switch SW9 is turned on in the first phase. The switch SW9 is turned off in the second phase.

Next, the operation of the amplifying circuit of FIG. 6 will be described.

In the prestage of the amplifying circuit of FIG. 6, the switches SW1, SW2 are turned on and the switch SW3 is turned off in the first phase. Thus, the input signal V_{IN} is sampled by the sampling capacitance Cs₁.

In the second phase, the switches SW1, SW2 are turned off and the switch SW3 is turned on. Thus, the input signal V_{IN}, which has been sampled by the sampling capacitance Cs₁, is output from the output terminal of the operational amplifier OP₁.

Meanwhile, in the poststage of the amplifying circuit of FIG. 6, the switches SW6, SW9 are turned off and the switches SW4, SW5, SW7, and SW8 are turned on in the second phase. Accordingly, the output signal of the operational amplifier OP₁ is sampled by the sampling capacitance Cs₂. The voltage of the inverted input terminal of the operational amplifier OP₁ is sampled by the level shift capacitance Ccls. Electric charge Qₛ₂ sampled by the sampling capacitance Cs₂ and electric charge Qcls sampled by the level shift capacitance Ccls are expressed according to the charge conservation law:

$${Q}_{s 2} = \frac{{A}_{1} {C}_{s 2} {V}_{in}}{1 + {A}_{1}}$$

$${Q}_{cls} = - \frac{{C}_{cls} {V}_{in}}{1 + {A}_{1}}$$

As can be seen from the equation above, if A₁ is sufficiently large, Qcls becomes 0. That is, the signal sampled by the level shift capacitance Ccls is an error signal caused by the limited gain A₁ of the operational amplifier OP₁.

In the first phase, the switches SW6, SW9 are turned on and the switches SW4, SW5, SW7, and SW8 are turned off. Accordingly, the signal sampled by the sampling capacitance Cs₂ and the level shift capacitance Ccls is held and the output signal V_{OUT} is output. V_{OUT} is expressed by the equation below according to the charge conservation law.

$${V}_{out} = \frac{{V}_{in}}{1 + 1 / {A}_{2}}$$

As can be seen from the above equation, the output signal V_{OUT} of the amplifying circuit according to the present embodiment does not rely on the gain A₁. This is because the error caused by the gain A₁ is canceled by sampling the error signal of the operational amplifier OP₁ by the level shift capacitance Ccls and adding the sampled error signal to the output signal of the operational amplifier OP₁.

As described above, the amplifying circuit according to the present embodiment equivalently improves the gain of the first operational amplifier OP₁ and decreases the amplifying error caused by the limited gain. Therefore, the amplifying circuit according to the present embodiment can realize a highly accurate buffer circuit. In addition, because the level shift capacitance Ccls is not connected to the output terminal of the operational amplifier OP₁, the power consumption of the circuit that drives the level shift capacitance Ccls can be decreased.

### Third Embodiment

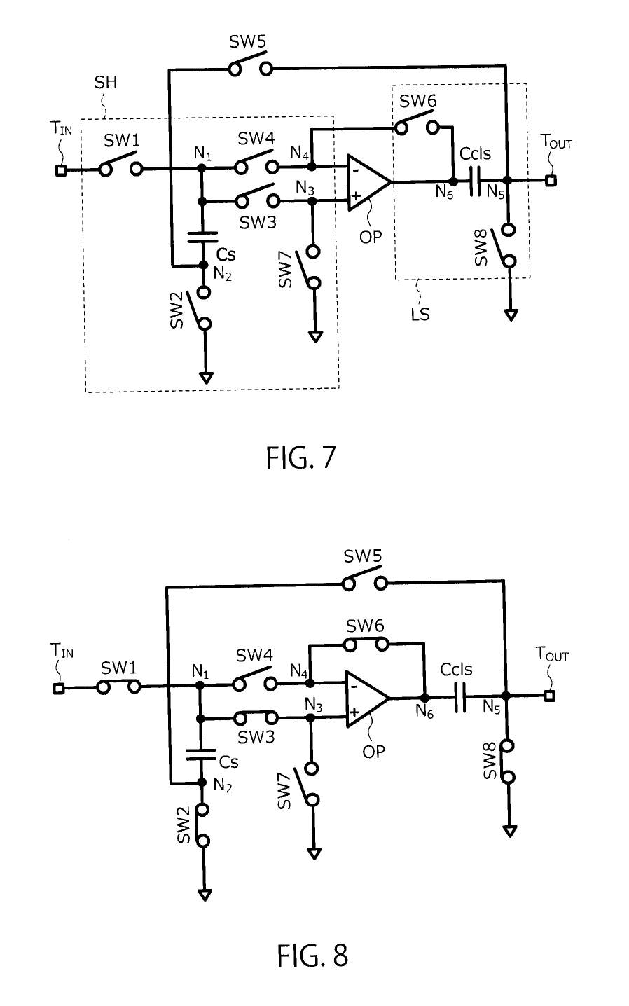

An amplifying circuit according to a third embodiment will be described by referring to FIGS. 7 to 12. FIG. 7 illustrates an amplifying circuit according to the present embodiment. The amplifying circuit according to the present embodiment is an amplifying circuit having a gain 1, i.e., a buffer circuit. As illustrated in FIG. 7, the amplifying circuit according to the present embodiment includes an analog input terminal T_{IN}, an analog output terminal T_{OUT}, a sample and hold circuit SH, an operational amplifier OP, a switch SW5, and a level shift circuit LS.

An analog input signal V_{IN} (referred to as an input signal V_{IN} hereinafter) is input to the analog input terminal T_{IN} (referred to as the input terminal T_{IN} hereinafter).

An analog output signal V_{OUT} (referred to as an output signal V_{OUT} hereinafter) is output from the analog output terminal T_{OUT} (referred to as the output terminal T_{OUT} hereinafter). The output signal V_{OUT} is a signal obtained by amplifying the input signal V_{IN} by the gain 1 in the amplifying circuit.

The sample and hold circuit SH is a switched capacitor circuit connected between the input terminal T_{IN} and the input terminal of the operational amplifier OP. The sample and hold circuit SH operates in two phases including the sampling phase and the amplifying phase. The sample and hold circuit SH includes a sampling capacitance Cs and five switches SW1 to SW4 and SW7.

The sampling capacitance Cs has its one end connected to a node N₁ and the other end connected to a node N₂. The node N₁ is a connection point between the sampling capacitance Cs and the switches SW1, SW3, and SW4. The node N₂ is a connection point between the sampling capacitance Cs and the switches SW2, SW5. The sampling capacitance Cs has a capacitance value Cs. The sampling capacitance Cs samples the input signal V_{IN} in the sampling phase. The sampling capacitance Cs holds the sampled input signal V_{IN} in the amplifying phase.

The switch SW1 has its one end connected to the input terminal T_{IN} and the other end connected to the node N₁. The switch SW2 has its one end connected to the node N₂ and the other end grounded. The switch SW3 has its one end connected to the node N₁ and the other end connected to the node N₃. The node N₃ is a connection point between the switches SW3, SW7 and the non-inverted input terminal of the operational amplifier OP. The switch SW4 has its one end connected to the node N₁ and the other end connected to the node N₄. The node N₄ is a connection point between the switches SW4, SW6 and the inverted input terminal of the operational amplifier OP. The switch SW7 has its one end connected to the node N₃ and the other end grounded.

In the sampling phase, the switches SW1 to SW3 are turned on and the switches SW4, SW7 are turned off. Accordingly, the input signal V_{IN} is sampled by the sampling capacitance Cs. The input signal V_{IN} is input to the non-inverted input terminal of the operational amplifier OP.

In the amplifying phase, the switches SW1 to SW3 are turned off and the switches SW4, SW7 are turned on. Accordingly, the input signal V_{IN}, which has been sampled by the sampling capacitance Cs, is held.

The operational amplifier OP amplifies and outputs the input signal V_{IN} having been held by the sampling capacitance Cs. The operational amplifier OP includes an inverted input terminal, a non-inverted input terminal, and an output terminal. The inverted input terminal is connected to the node N₄. The non-inverted input terminal is connected to the node N₃. The output terminal is connected to the level shift circuit LS.

The switch SW5 has its one end connected to the node N₂ and the other end connected to the node N₅. The node N₅ is a connection point among the switches SW5, SW8, the level shift capacitance Ccls, and the output terminal T_{OUT}. That is, the switch SW5 is connected between the sampling capacitance Cs and the output terminal T_{OUT}. The switch SW5 is turned off in the sampling phase. The switch SW5 is turned on in the amplifying phase.

The level shift circuit LS is a switched capacitor circuit connected between the output terminal of the operational amplifier OP and the output terminal T_{OUT}. The level shift circuit LS operates in two phases including the sampling phase and the amplifying phase. The level shift circuit LS includes a level shift capacitance Ccls and two switches SW6, SW8.

The level shift capacitance Ccls has its one end connected to the node N₅ and the other end connected to the node N₆. The node N₆ is a connection point among the level shift capacitance Ccls, the switch SW6, and the output terminal of the operational amplifier OP. The level shift capacitance Ccls has a capacitance value Ccls. The level shift capacitance Ccls samples the output signal of the operational amplifier OP during the sampling phase. Also, the level shift capacitance Ccls holds the sampled output signal of the operational amplifier OP during the amplifying phase.

The switch SW6 has its one end connected to the node N₄ and the other end connected to the node N₆. The switch SW8 has its one end connected to the node N₅ and the other end grounded.

In the sampling phase, the switches SW6, SW8 are turned on, such that the output signal of the operational amplifier OP is sampled by the level shift capacitance Ccls.

In the amplifying phase, the switches SW6, SW8 are turned off to hold the output signal of the operational amplifier OP sampled by the level shift capacitance Ccls.

Next, the operation of the amplifying circuit of FIG. 7 will be described.

FIG. 8 illustrates the amplifying circuit of FIG. 7 in the sampling phase. As illustrated in FIG. 8, the switches SW1, SW2, SW3, SW6, and SW8 are turned on, and the switches SW4, SW5, and SW7 are turned off in the sampling phase.

Accordingly, the input signal V_{IN} is sampled by the sampling capacitance Cs. The input signal V_{IN} is input to the non-inverted input terminal of the operational amplifier OP. Since the switch SW6 is in the on-state at this time, the operational amplifier OP functions as a voltage follower. Accordingly, the input signal V_{IN}, which has been input to the non-inverted input terminal, is output from the output terminal of the operational amplifier OP. The input signal V_{IN} is output from the operational amplifier OP and is sampled by the level shift capacitance Ccls.

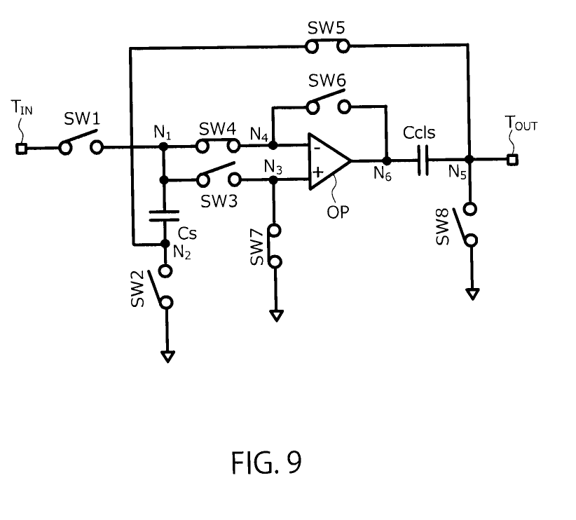

FIG. 9 illustrates the amplifying circuit of FIG. 7 in the amplifying phase. As illustrated in FIG. 9, the switches SW1, SW2, SW3, SW6, and SW8 are turned off, and the switches SW4, SW5, and SW7 are turned on in the amplifying phase.

Accordingly, the inverted input terminal of the operational amplifier OP is connected to the output terminal T_{OUT} via the sampling capacitance Cs. Thus, the signal obtained by amplifying the input signal V_{IN}, which has been sampled by the sampling capacitance Cs with a gain 1, is output as the output signal V_{OUT}.

Since the level shift capacitance Ccls holds the input signal V_{IN} in the amplifying phase, the gain of the operational amplifier OP can be improved equivalently. Thus, the amplifying error caused by the limited gain of the operational amplifier OP can be suppressed. Therefore, the amplifying circuit according to the present embodiment can realize a highly accurate buffer circuit. In addition, by using the operational amplifier OP as the voltage follower, the level shift capacitance Ccls can be driven without adding circuits or increasing power consumption.

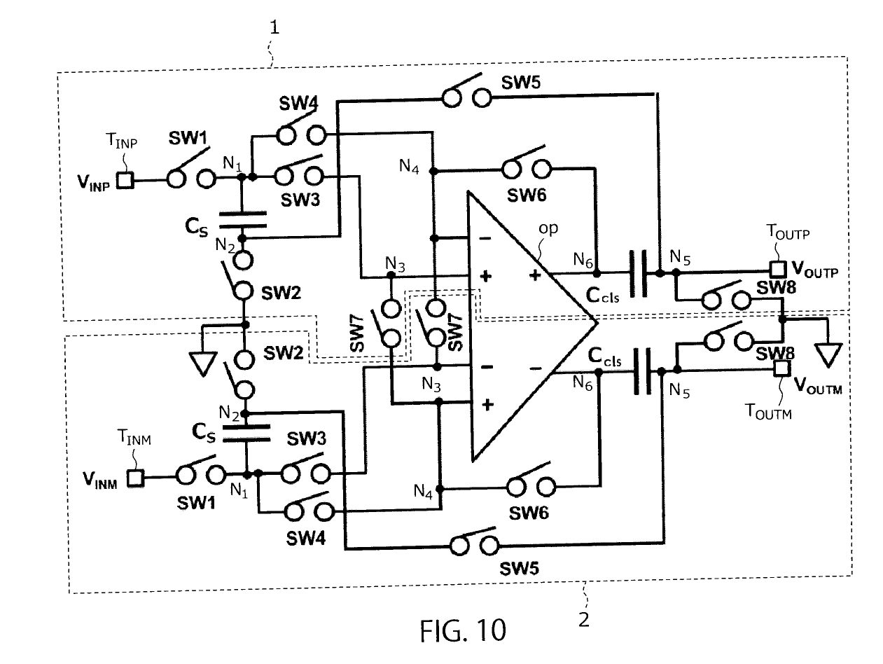

FIG. 10 illustrates a differential amplifying circuit formed by the amplifying circuit of FIG. 7 having a differential structure. The amplifying circuit of FIG. 10 receives differential input signals V_{INP}, V_{INM} and outputs differential output signals V_{OUTP}, V_{OUTM}. As illustrated in FIG. 10, the amplifying circuit includes a first amplifying circuit 1 and a second amplifying circuit 2.

The first amplifying circuit 1 includes an input terminal T_{INP}, an output terminal T_{OUTP}, a sample and hold circuit SH, a full differential operational amplifier op, a switch SW5, and a level shift circuit LS. The first amplifying circuit 1 receives the input signal V_{INP} from the input terminal T_{INP}, and outputs the output signal V_{OUTP} from the output terminal T_{OUTP}. The first amplifying circuit 1 is similar to the amplifying circuit of FIG. 7, except for the full differential operational amplifier op and a switch SW7.

The second amplifying circuit 2 includes an input terminal T_{INM}, an output terminal T_{OUTM}, a sample and hold circuit SH, the full differential operational amplifier op, a switch SW5, and a level shift circuit LS. The second amplifying circuit 2 receives the input signal V_{INM} from the input terminal T_{INM} and outputs the output signal V_{OUTM} from the output terminal T_{OUTM}. The input signal V_{INM} and the output signal V_{OUTM} are differential signals (reversed phase signals) of the input signal V_{INP} and the output signal V_{OUTP}, respectively. The second amplifying circuit 2 is similar to the amplifying circuit of FIG. 7, except for the full differential operational amplifier op and the switch SW7.

The full differential operational amplifier op is used by both the first and second amplifying circuits 1, 2. The full differential operational amplifier op includes a first inverted input terminal, a first non-inverted input terminal, a second inverted input terminal, a second non-inverted input terminal, a non-inverted output terminal, and an inverted output terminal.

The first inverted input terminal is connected to the node N₄ of the first amplifying circuit 1. The first non-inverted input terminal is connected to the node N₃ of the first amplifying circuit 1. The second inverted input terminal is connected to the node N₃ of the second amplifying circuit 2. The second non-inverted input terminal is connected to the node N₄ of the second amplifying circuit 2. The non-inverted output terminal is connected to the node N₆ of the first amplifying circuit 1. The inverted output terminal is connected to the node N₆ of the second amplifying circuit 2.

The other end of the switch SW7 is grounded in the amplifying circuit of FIG. 7. In the amplifying circuit of FIG. 10, however, the other end of the switch SW7 of the first amplifying circuit 1 is connected to the node N₃ of the second amplifying circuit 2. One end of the switch SW7 of the second amplifying circuit 2 is connected to the node N₃ of the first amplifying circuit 1.

With this structure, the amplifying circuit of FIG. 7 has a differential structure. Since the full differential operational amplifier op functions as a voltage follower, the amplifying circuit of FIG. 10 can achieve an effect similar to that of the amplifying circuit of FIG. 7.

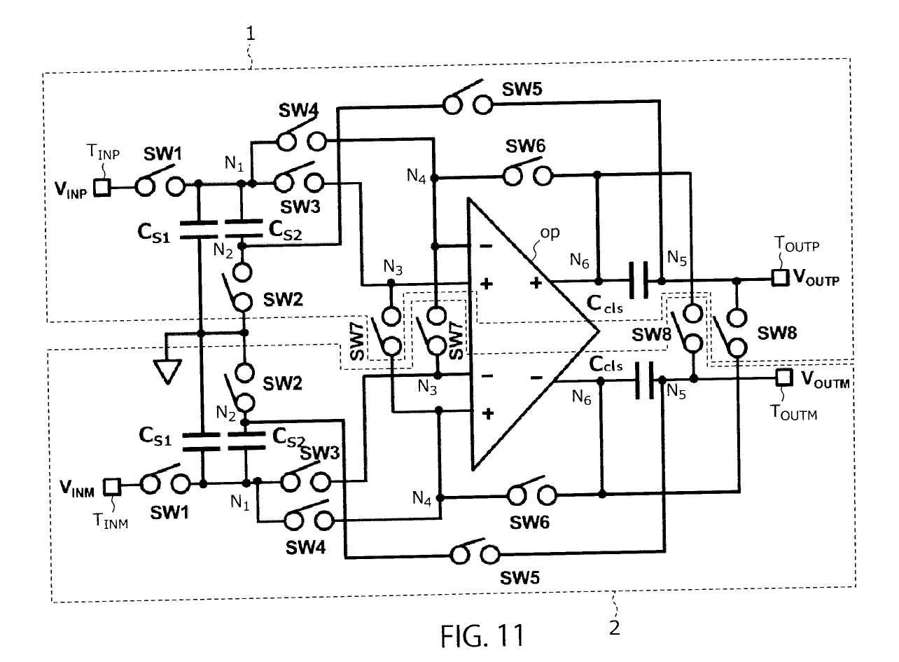

FIG. 11 illustrates a variation of the amplifying circuit of FIG. 10. In the amplifying circuit of FIG. 11, the other end of the first amplifying circuit 1 is connected to the node N₆ of the second amplifying circuit 2. The other end of the second amplifying circuit 2 is connected to the node N₆ of the first amplifying circuit 1.

The sample and hold circuits SH of the first and second amplifying circuits 1, 2 each has two sampling capacitances Cs₁, Cs₂. The sampling capacitance Cs₂ corresponds to the sampling capacitance Cs of FIG. 7. That is, the sample and hold circuits SH of the first and second amplifying circuits 1, 2, respectively, further include the sampling capacitance Cs₁. Other portions of the structure of the first and second amplifying circuits 1, 2 are similar to those of FIG. 10.

The sampling capacitance Cs₁ of the sample and hold circuit SH of the first amplifying circuit 1 has its one end connected to the node N₁ of the first amplifying circuit 1, and the other end grounded. The sampling capacitance Cs₁ samples the input signal V_{INP} in the sampling phase. In the amplifying phase, the sampling capacitance Cs₁ holds the sampled input signal V_{INP}.

The sampling capacitance Cs₁ of the sample and hold circuit SH of the second amplifying circuit 2 has its one end connected to the node N₁ of the second amplifying circuit 2 and the other end grounded. Accordingly, the sampling capacitance Cs₁ samples the input signal V_{INM} in the sampling phase. In the amplifying phase, the sampling capacitance Cs₁ holds the sampled input signal V_{INM}.

With this structure, the amplifying circuit of FIG. 11 can be realized as a flip-around type differential amplifying circuit. The gain of the amplifying circuit is 1+Cs₁/Cs₂. Therefore, by adjusting the capacitance values of the sampling capacitances Cs₁, Cs₂, the gain of the amplifying circuit can be changed and the amplifying circuit can be used for other applications than the buffer circuit. For example, when the capacitance values of the sampling capacitances Cs₁, Cs₂ are equal (Cs₁=Cs₂), the amplifying circuit of FIG. 11 can function as a double amplifying circuit.

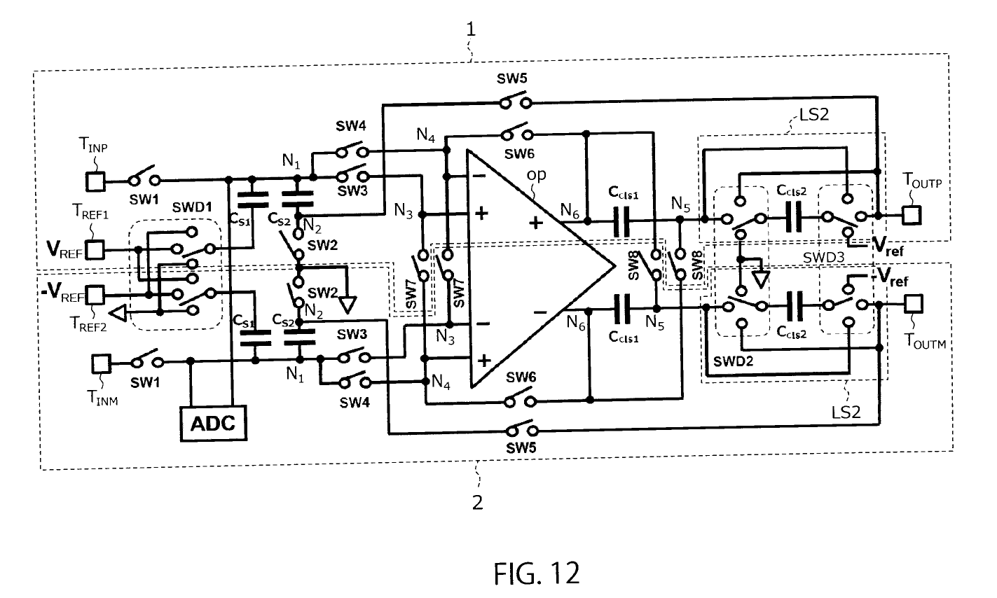

FIG. 12 illustrates a variation of the amplifying circuit of FIG. 11. The amplifying circuit of FIG. 12 includes a positive reference signal input terminal T_{REF1}, a negative reference signal input terminal T_{REF2}, an A-D converter (ADC). The first and second amplifying circuits 1, 2 each has a switch SWD1 and a second level shift circuit LS2. The level shift capacitance Ccls1 of FIG. 12 corresponds to the level shift capacitance Ccls of FIG. 11. Other portions of the structure of the amplifying circuit of FIG. 12 are similar to those of FIG. 11.

A positive reference signal is input to the positive reference signal input terminal T_{REF1} (referred to as the input terminal T_{REF1} hereinafter). The positive reference signal is represented by V_{REF}. A negative reference signal is input to the negative reference signal input terminal T_{REF2} (referred to as the input terminal T_{REF2} hereinafter). The negative reference signal is represented by −V_{REF}.

The A-D converter has two input terminals each connected to the node N₁ of the first and second amplifying circuits 1, 2. The A-D converter operates in synchronism with the sampling phase and the amplifying phase of the amplifying circuit. The A-D converter compares, during the amplifying phase, the input signals V_{INP}, V_{INM} sampled at the end of the sampling phase (i.e., the input signals V_{INP}, V_{INM} held by the sampling capacitances Cs₁, Cs₂ in the amplifying phase), with a common-mode voltage V_{COM} of the input signals V_{INP}, V_{INM}. Then the A-D converter outputs a binary signal corresponding to the comparison result to the first and second amplifying circuits 1, 2. The A-D converter herein outputs High when V_{INP}, V_{INM}>V_{COM} and outputs Low when V_{INP}, V_{INM}<V_{COM}. The switching of the switches SWD1, SWD2, and SWD3 in the amplifying phase is controlled by the output signal of the A-D converter. The A-D converter may be implemented as a comparator.

The switch SWD1 and the level shift circuit LS2 of the first amplifying circuit 1 will be described below. All constituent elements described below are included in the first amplifying circuit 1.

The switch SWD1 of the first amplifying circuit 1 has its one end connected to the other end of the sampling capacitance Cs₁. The other end of the switch SWD1 switches among the input terminal T_{REF1}, the input terminal T_{REF2}, and the ground line.

The level shift circuit LS2 (second level shift circuit) of the first amplifying circuit 1 is a switched capacitor circuit connected between the level shift capacitance Ccls1 and the output terminal T_{OUTP}. The level shift circuit LS2 operates in two phases including the sampling phase and the amplifying phase. The level shift circuit LS2 includes the level shift capacitance Ccls2 and the switches SWD2, SWD3.

The level shift capacitance Ccls2 samples the positive reference signal V_{REF} in the sampling phase and holds it in the amplifying phase. The level shift capacitance Ccls2 has its one end connected to one end of the switch SWD2 and the other end connected to one end of the switch SWD3.

The switch SWD2 has its one end connected to one end of the level shift capacitance Ccls2. The other end of the switch SWD2 is switchable among the output terminal T_{OUTP}, the node N₅, and the ground line.

The switch SWD3 has its one end connected to the other end of the level shift capacitance Ccls2. The other end of the switch SWD3 is switchable among the node N₅, the output terminal T_{OUTP}, and the input terminal T_{REF1}.

The switching of the switches SWD1 to SWD3 of the first amplifying circuit 1 in the amplifying phase is controlled by the signal output from the first amplifying circuit 1 by the A-D converter.

Next, the switch SWD1 and the level shift circuit LS2 of the second amplifying circuit 2 will be described below. All constituent elements described below are included in the second amplifying circuit 2.

The switch SWD1 of the second amplifying circuit 2 has its one end connected to the other end of the sampling capacitance Cs₁. The other end of the switch SWD1 switches among the input terminal T_{REF1}, the input terminal T_{REF2}, and the ground line.

The level shift circuit LS2 (second level shift circuit) of the second amplifying circuit 2 is a switched capacitor circuit connected between the level shift capacitance Ccls1 and the output terminal T_{OUTM}. The level shift circuit LS2 operates in two phases including the sampling phase and the amplifying phase. The level shift circuit LS2 includes the level shift capacitance Ccls2 and the switches SWD2, SWD3.

The level shift capacitance Ccls2 samples the negative reference signal −V_{REF} in the sampling phase and holds it in the amplifying phase. The level shift capacitance Ccls2 has its one end connected to one end of the switch SWD2 and the other end connected to one end of the switch SWD3.

The switch SWD2 has its one end connected to one end of the level shift capacitance Ccls2. The other end of the switch SWD2 is switchable among the output terminal T_{OUTM}, the node N₅, and the ground line.

The switch SWD3 has its one end connected to the other end of the level shift capacitance Ccls2. The other end of the switch SWD3 is switchable among the node N₅, the output terminal T_{OUTM}, and the input terminal T_{REF2}.

The switching of the switches SWD1 to SWD3 of the second amplifying circuit 2 in the amplifying phase is controlled by the output signal output to the second amplifying circuit 2 by the A-D converter.

In the amplifying circuit, the switch SWD1 is grounded in the sampling phase. Accordingly, the input signal V_{INP} is sampled by the sample capacitance Cs₁ of the first amplifying circuit 1, and the input signal V_{INM} is sampled by the sampling capacitance Cs₁ of the second amplifying circuit 2. The other end of the switch SWD2 is grounded, and the other end of the switch SWD3 is connected to the input terminals T_{REF1} and T_{REF2}. Accordingly, the positive reference signal V_{REF} is sampled by the level shift capacitance Ccls2 of the first amplifying circuit 1, and the negative reference signal −V_{REF} is sampled by the level shift capacitance Ccls2 of the second amplifying circuit 2.

In the amplifying phase, when the A-D converter outputs High to the first amplifying circuit 1, the other end of the switch SWD1 of the first amplifying circuit 1 is connected to the input terminal T_{REF2}, the other end of the switch SWD2 is connected to the output terminal T_{OUTP}, and the other end of the switch SWD3 is connected to the node N₅. Accordingly, the output signal V_{OUTP} becomes a signal formed by adding the reference signal V_{REF} to the voltage whose level has been shifted by the level shift capacitance Ccls1 of the first amplifying circuit 1.

Since the input signals V_{INP}, V_{INM} are differential signals, the A-D converter outputs Low to the second amplifying circuit 2 when the A-D converter outputs High to the first amplifying circuit 1. At this time, the other end of the switch SWD1 of the second amplifying circuit 2 is connected to the input terminal T_{REF1}, the other end of the switch SWD2 is connected to the output terminal T_{OUTM}, and the other end of the switch SWD3 is connected to the node N₅. Accordingly, the output signal V_{OUTM} becomes a signal formed by subtracting the reference signal V_{REF} from the voltage whose level has been shifted by the level shift capacitance Ccls1 of the second amplifying circuit 2.

In the amplifying phase, when the A-D converter has outputted Low to the first amplifying circuit 1, the other end of the switch SWD1 of the first amplifying circuit 1 is connected to the input terminal T_{REF1}, the other end of the switch SWD2 is connected to the node N₅, and the other end of the switch SWD3 is connected to the output terminal T_{OUTP}. Accordingly, the output signal V_{OUTP} becomes a signal formed by subtracting the reference signal V_{REF} from the voltage whose level has been shifted by the level shift capacitance Ccls1 of the first amplifying circuit 1.

Since the input signals V_{INP}, V_{INM} are differential signals, the A-D converter outputs High to the second amplifying circuit 2 when the A-D converter outputs Low to the first amplifying circuit 1. At this time, the other end of the switch SWD1 of the second amplifying circuit 2 is connected to the input terminal T_{REF2}, the other end of the switch SWD2 is connected to the node N₅, and the other end of the switch SWD3 is connected to the output terminal T_{OUTM}. Accordingly, the output signal V_{OUTM} becomes a signal formed by adding the reference signal V_{REF} to the voltage whose level has been shifted by the level shift capacitance Ccls1 of the second amplifying circuit 2.

With this structure, the amplifying circuit of FIG. 12 can add/subtract the reference signal, as well as the amplification of the input signal V_{IN}. Thus, the amplifying circuit of FIG. 12 can be used as a residual amplifying circuit, such the MDAC.

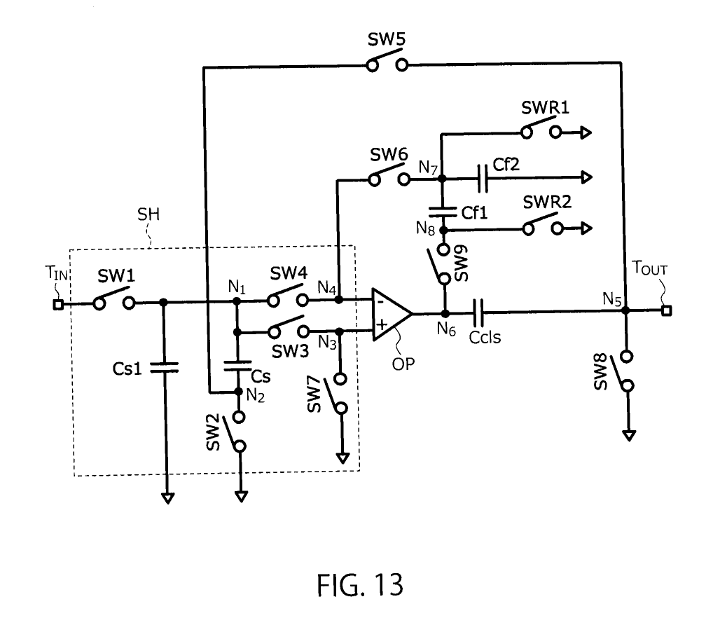

FIG. 13 illustrates a variation of the amplifying circuit of FIG. 7. The amplifying circuit of FIG. 13 further includes feedback capacitances Cf1, Cf2, switches SW9, SWR1, and SWR2, and a sampling capacitance Cs₁. Other portions of the structure of the amplifying circuit of FIG. 13 are similar to those of FIG. 7.

The feedback capacitance Cf1 has its one end connected to the node N₇ and the other end connected to a node N₈. The node N₇ is a connection point between the switches SW6, SWR1, and the feedback capacitances Cf1, Cf2. The node N₈ is a connection point between the switches SW9, SWR2, and the feedback capacitance Cf1. The feedback capacitance Cf1 has a capacitance value Cf1.

The feedback capacitance Cf2 has its one end connected to the node N₇ and the other end grounded. The feedback capacitance Cf2 has a capacitance value Cf2.

The switch SW9 has its one end connected to the node N₆ and the other end connected to the node N₈. The switch SWR1 has its one end connected to the node N₇ and the other end grounded. The switch SWR2 has its one end connected to the node N₈ and the other end grounded.

The sampling capacitance Cs₁ corresponds to the sampling capacitance Cs₁ of the amplifying circuit of FIG. 11. The sampling capacitance Cs₁ has a capacitance value Cs₁. The sampling capacitances Cs, Cs₁ and the feedback capacitances Cf1, Cf2 are set such that the capacitance values are Cf2/Cf1=Cs₁/Cs.

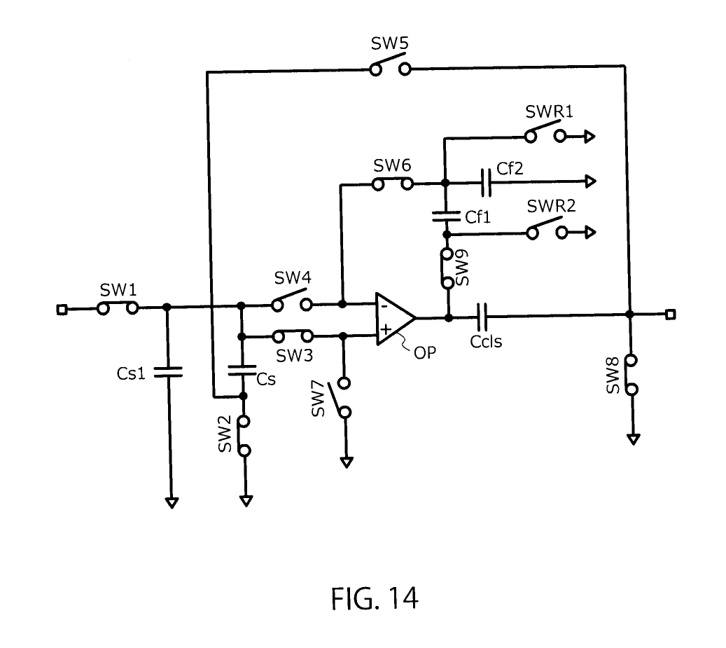

FIG. 14 illustrates the amplifying circuit of FIG. 13 during the sampling phase. As illustrated in FIG. 14, the switch SW9 of the amplifying circuit is turned on and the switches SWR1, SWR2 are turned off in the sampling phase. Accordingly, the amplifying circuit operates as a non-inverted amplifying circuit. Thus, the input signal V_{IN} amplified by the non-inverted amplifying circuit is sampled by the level shift capacitance Ccls.

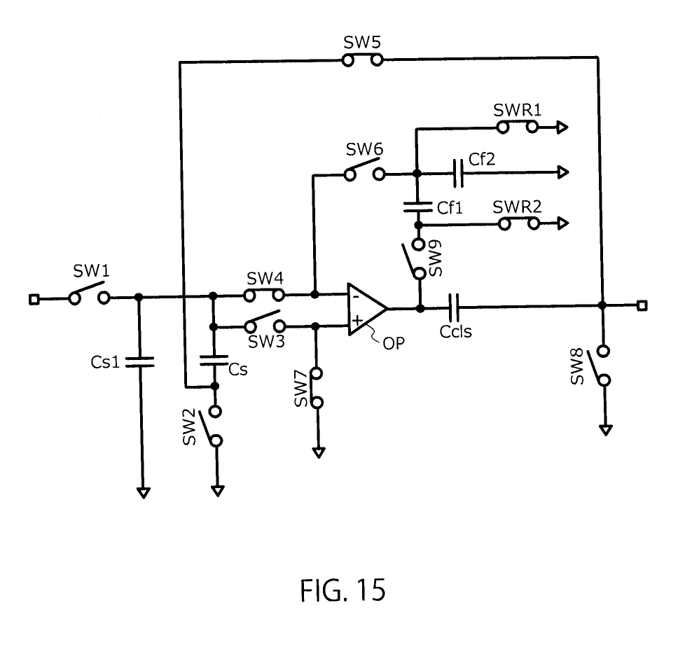

FIG. 15 illustrates the amplifying circuit of FIG. 13 in the amplifying phase. As illustrated in FIG. 15, the switch SW9 of the amplifying circuit is turned off and the switches SWR1, SWR2 are turned on in the amplifying phase. Accordingly, the electric charge accumulated in the feedback capacitances Cf1, Cf2 are reset.

With this structure, the amplifying circuit of FIG. 7 can be used not only as the buffer circuit but also as the amplifying circuit with the gain of 1+Cs₁/Cs.

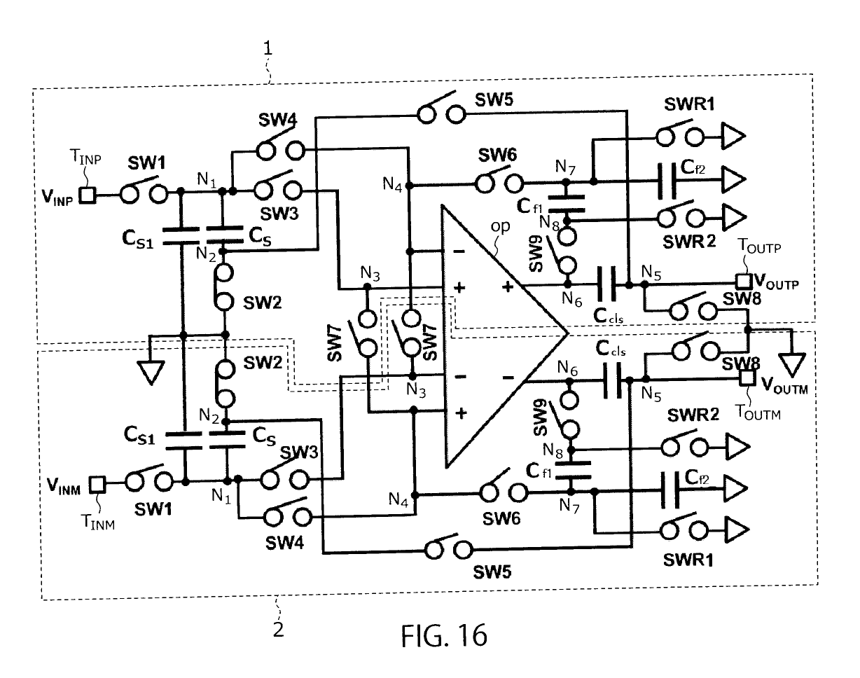

FIG. 16 illustrates a differential amplifying circuit formed by the amplifying circuit of FIG. 13 having a differential structure. The amplifying circuit of FIG. 16 receives differential input signals V_{INP} and V_{INM}, and outputs differential output signals V_{OUTP} and V_{OUTM}. As illustrated in FIG. 16, the amplifying circuit includes a first amplifying circuit 1 and a second amplifying circuit 2.

The first amplifying circuit 1 includes the input terminal T_{INP}, the output terminal T_{OUTP}, the sample and hold circuit SH, a full differential operational amplifier op, the switch SW5, and the level shift circuit LS. The first amplifying circuit 1 receives the input signal V_{INP} from the input terminal T_{INP}, and outputs the output signal V_{OUTP} from the output terminal T_{OUTP}. The first amplifying circuit 1 is similar to the amplifying circuit of FIG. 13, except for the full differential operational amplifier op and a switch SW7.

The second amplifying circuit 2 includes the input terminal T_{INM}, the output terminal T_{OUTM}, the sample and hold circuit SH, the full differential operational amplifier op, the switch SW5, and the level shift circuit LS. The second amplifying circuit 2 receives the input signal V_{INM} from the input terminal T_{INM} and outputs the output signal V_{OUTM} from the output terminal T_{OUTM}. The input signal V_{INM} and the output signal V_{OUTM} are differential signals (reversed phase signals) of the input signal V_{INP} and the output signal V_{OUTP}, respectively. The second amplifying circuit 2 is similar to the amplifying circuit of FIG. 13, except for the full differential operational amplifier op and a switch SW7.

The full differential operational amplifier op is used by both the first and second amplifying circuits 1, 2. The full differential operational amplifier op includes a first inverted input terminal, a first non-inverted input terminal, a second inverted input terminal, a second non-inverted input terminal, a non-inverted output terminal, and an inverted output terminal.

The first inverted input terminal is connected to the node N₄ of the first amplifying circuit 1. The first non-inverted input terminal is connected to the node N₃ of the first amplifying circuit 1. The second inverted input terminal is connected to the node N₃ of the second amplifying circuit 2. The second non-inverted input terminal is connected to the node N₄ of the second amplifying circuit 2. The non-inverted output terminal is connected to the node N₆ of the first amplifying circuit 1. The inverted output terminal is connected to the node N₆ of the second amplifying circuit 2.

The other end of the switch SW7 is grounded in the amplifying circuit of FIG. 13. In the amplifying circuit of FIG. 16, however, the other end of the switch SW7 of the first amplifying circuit 1 is connected to the node N₃ of the second amplifying circuit 2. One end of the switch SW7 of the second amplifying circuit 2 is connected to the node N₃ of the first amplifying circuit 1.

With this structure, the amplifying circuit of FIG. 13 has a differential structure. The amplifying circuit of FIG. 16 can achieve an effect similar to that of the amplifying circuit of FIG. 13.

### Fourth Embodiment

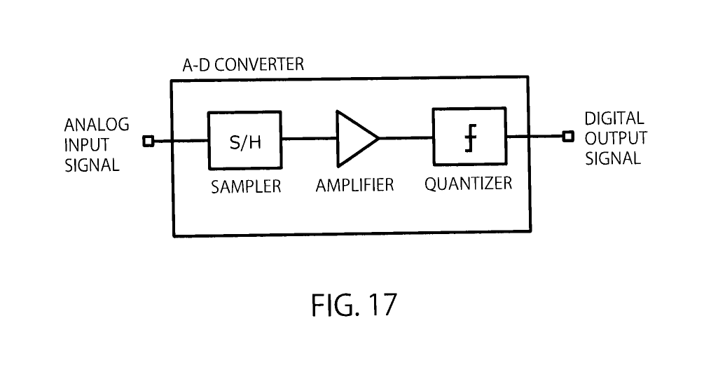

An A-D converter according to a fourth embodiment will be described by referring to FIG. 17. FIG. 17 is a functional block diagram of an A-D converter according to the present embodiment. The A-D converter according to the present embodiment includes the amplifying circuit according to any one of the first to third embodiments described above. As illustrated in FIG. 17, the A-D converter includes a sampler, an amplifier, and a quantizer.

The sampler samples a received analog input signal at predetermined time intervals and outputs a sampled signal. The amplifier amplifies the signal output from the sampler with a predetermined gain and outputs an amplified signal. The quantizer quantizes the signal output from the amplifier and outputs a digital output signal.

In the A-D converter according to the present embodiment, the sampler and the amplifier are formed by the amplifying circuit according to any one of the embodiments 1 to 3 above. The function of the sampler is realized by the sample and hold circuit SH of the amplifying circuit. The function of the amplifier is realized by the entire amplifying circuit. The output signal V_{OUT} of the amplifying circuit becomes the output signal of the amplifier. The output signal V_{OUT} is quantized by the quantizer.

The amplifying circuits according to the embodiments described above can equivalently improve the gain of the operational amplifier OP by the level shift circuit LS, and enables highly accurate amplification. With only two operation phases being provided, such amplifying circuits can operate at high speed faster than the amplifying circuit of the past that operates using the CLS technique.

Since such amplifying circuits are provided as samplers and amplifiers, the A-D converter according to the present embodiment enables highly accurate and high speed A-D conversion. That is, the sampling frequency can be increased and the quantization error can be reduced.

### Fifth Embodiment

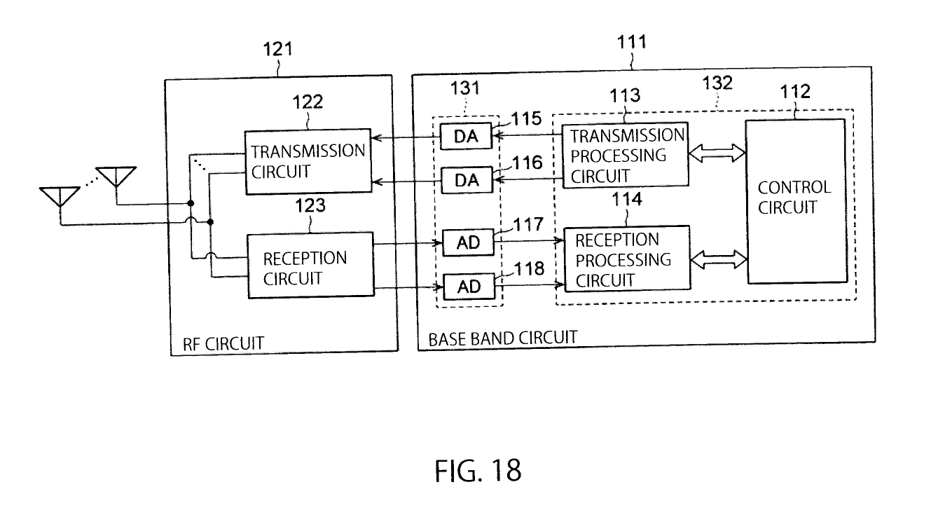

An integrated circuit and a radio communication apparatus according to a fifth embodiment will be described by referring to FIG. 18. FIG. 18 is a block diagram illustrating the hardware structure of a radio communication apparatus according to the present embodiment. The hardware structure illustrated herein is provided only as an example, and various other variations are possible.

As illustrated in FIG. 18, the radio communication apparatus according to the present embodiment includes a base band circuit 111, a radio frequency (RF) circuit 121, and an antenna.

The base band circuit 111 includes a control circuit 112, a transmission processing circuit 113, a reception processing circuit 114, digital-to-analog (D-A) converters 115, 116, and A-D converters 117, 118. The RF circuit 121 and the base band circuit 111 may be formed together as a single chip integrated circuit (IC), or may be formed separately by individual chips.

The base band circuit 111 may be, for example, a single-chip base band large-scale-integration (LSI) circuit or a base band IC. The base band circuit 111 may include two chips of ICs including an IC131 and an IC132, as indicated by a broken line in FIG. 18. In the example of FIG. 18, the IC131 includes D-A converters 115, 116 and A-D converters 117, 118. The IC132 includes the control circuit 112, the transmission processing circuit 113, and the reception processing circuit 114. Constituent elements to be distributed in each IC are not limited thereto. The base band circuit 111 may be formed by at least three ICs.

The control circuit 112 performs processing related to communication with other terminals (including a base station). Specifically, the control circuit 112 handles three types of media access (MAC) frames including a data frame, a control frame, and a management frame, and executes various types of processing defined in the MAC layer. The control circuit 112 may also execute processing in an upper layer above the MAC layer (e.g., TCP/IP (transmission control protocol/Internet protocol), UDP/IP (user datagram protocol/Internet protocol), or upper application layers).

The transmission processing circuit 113 receives the MAC frame from the control circuit 112. The transmission processing circuit 113 adds a preamble and a physical (PHY) header to the MAC frame, and encodes and modulates the MAC frame. Accordingly, the transmission processing circuit 113 converts the MAC frame into a PHY packet.

The D-A converters 115, 116 performs D-A conversion of the PHY packet output from the transmission processing circuit 113. In the example of FIG. 18, two systems of D-A converters are provided and arranged in parallel with each other. Alternatively, a single D-A converter may be provided, or a number of D-A converters equivalent to the antennas may be provided.

The RF circuit 121 may be, for example, a single chip RF analog IC or a high frequency IC. The RF circuit 121 may be formed in a single chip together with the base band circuit 111, or may be formed in two chips of the IC including a transmission circuit 122 and the IC including a reception processing circuit. The RF circuit 121 includes a transmission circuit 122 and a reception circuit 123.

The transmission circuit 122 performs analog signal processing of a PHY packet, which has been subjected to D-A conversion by the D-A converters 115, 116. The analog signal output from the transmission circuit 122 is transmitted by radio via the antenna. The transmission circuit 122 includes a transmission filter, a mixer, a power amplifier (PA), and so on.

The transmission filter extracts a signal of a desired band from the signal of the PHY packet that has been subjected to the D-A conversion by the D-A converters 115, 116. The mixer uses a signal having a predetermined frequency supplied from the oscillator to upconvert a filtered signal having been filtered by a transmission filter to a radio frequency. A preamplifier amplifies the upconverted signal. An amplified signal is supplied to the antenna, and a radio signal is transmitted.

The reception circuit 123 performs analog signal processing of the signal received by the antenna. The reception circuit 123 outputs a signal which is input to the A-D converters 117, 118. The reception circuit 123 includes a low noise amplifier (LNA), a mixer, a reception filter, etc.

The LNA amplifies the signal received by the antenna. The mixer uses a signal having a predetermined frequency supplied from the oscillator to downconvert an amplified signal to a radio frequency. The reception filter extracts a signal of a desired band from the downconverted signal. The extracted signal is input to the A-D converters 117, 118.

The A-D converters 117, 118 performs A-D conversion of the input signal from the reception circuits 123. In the example of FIG. 18, two systems of A-D converters are provided and arranged in parallel with each other. Alternatively, a single A-D converter may be provided, or a number of A-D converters equivalent to the antennas may be provided.

The radio communication apparatus according to the present embodiment includes the A-D converters according to the fourth embodiment as the A-D converters 117, 118. Since the A-D converters according to the fourth embodiment can perform highly accurate and high speed A-D conversion, the radio communication apparatus according to the present embodiment can perform high speed and highly reliable reception processing of the radio signal.

The reception processing circuit 114 receives the PHY packet after being subjected to A-D conversion by the A-D converters 117, 118. The reception processing circuit 114 demodulates and decodes the PHY packet, and removes the preamble and the PHY header from the PHY packet. Accordingly, the reception processing circuit 114 converts the PHY packet into the MAC frame. The frame processed by the reception processing circuit 114 is input into the control circuit 112.

Although the D-A converters 115, 116 and the A-D converters 117, 118 are arranged in the base band circuit 111 in the example of FIG. 18, they may be arranged in the RF circuit 121.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An amplifying circuit, comprising:
an analog input terminal to receive an analog input signal;
an analog output terminal to output an analog output signal;
a sample and hold circuit including a sampling capacitance to sample the analog input signal in a sampling phase and to hold the sampled signal in an amplifying phase, and a plurality of switches, each switching between the sampling phase and the amplifying phase;
an operational amplifier including an input terminal connected to the sample and hold circuit, an output terminal, the operational amplifier amplifying and outputting the analog input signal held by the sampling capacitance in the amplifying phase;
a feedback capacitance connected between the input terminal of the operational amplifier and the analog output terminal; and
a level shift circuit including at least one level shift capacitance to sample the analog input signal in the sampling phase and to hold the sampled analog input signal in the amplifying phase, and a plurality of switches, each switching between the sampling phase and the amplifying phase, wherein
the at least one level shift capacitance comprises a plurality of level shift capacitances connected in cascade between the output terminal of the operational amplifier and the analog output terminal.

2. The amplifying circuit according to claim 1, wherein
a capacitance value of the sampling capacitance is an X times multiple of the feedback capacitance, where X is an integer equal to or larger than 2, and
the level shift capacitance comprises X level shift capacitances connected in cascade.

3. The amplifying circuit according to claim 1 configured to have a differential structure.

4. The amplifying circuit according to claim 1, further comprising:
a buffer circuit connected between the level shift circuit and the analog output terminal.

5. The amplifying circuit according to claim 1, further comprising:
a second level shift circuit arranged between the level shift circuit and the analog output terminal, the second level shift circuit including
a second level shift capacitance that samples a reference signal in the sampling phase and holds the sampled reference signal in the amplifying phase, and
a plurality of switches, each switching between the sampling phase and the amplifying phase.

6. An amplifying circuit, comprising:
an analog input terminal to receive an analog input signal;
an analog output terminal to output an analog output;
a first sample and hold circuit including a first sampling capacitance to sample the analog input signal in a first phase and to hold the sampled signal in a second phase, and a plurality of switches, each switching between the first phase and the second phase;
a first operational amplifier including an input terminal connected to the first sample and hold circuit, and an output terminal, the first operational amplifier amplifying and outputting the analog input signal held by the first sampling capacitance in the second phase;
a first switch connected between the first sampling capacitance and the output terminal of the first operational amplifier;
a second sample and hold circuit including a second sampling capacitance to sample the output signal of the first operational amplifier in the second phase and to hold the sampled output signal in the first phase, and a plurality of switches, each switching between the first phase and the second phase;
a level shift circuit including a level shift capacitance to sample a signal at the input terminal of the first operational amplifier in the second phase and to hold the sampled signal in the first phase, and a plurality of switches, each switching between the first phase and the second phase;
a second operational amplifier including an input terminal connected to the level shift circuit, and an output terminal, the second operational amplifier amplifying and outputting the signal held in the second sampling capacitance and the level shift capacitance in the first phase; and
a second switch connected between the second sampling capacitance and the output terminal of the second operational amplifier.

7. An amplifying circuit, comprising:
an analog input terminal to which an analog input signal is input;
an analog output terminal from which an analog output signal is output;
a sample and hold circuit including a sampling capacitance to sample the analog input signal in a sampling phase and to hold the sampled input signal in an amplifying phase, and a plurality of switches, each switching between the sampling phase and the amplifying phase;
an operational amplifier including an input terminal and an output terminal, the operational amplifier outputting the analog input signal in the sampling phase and amplifying and outputting the analog input signal held by the sampling capacitance in the amplifying phase;
a switch connected between the sampling capacitance and the analog output terminal; and
a level shift circuit including a level shift capacitance to samples the output signal of the first operational amplifier in the sampling phase and to hold the sampled signal in the amplifying phase, and a plurality of switches, each switching between the sampling phase and the amplifying phase.

8. The amplifying circuit according to claim 7, configured to have a differential structure.

9. The amplifying circuit according to claim 7, further comprising:
a second level shift circuit arranged between the level shift circuit and the analog output terminal, the second level shift circuit including
a second level shift capacitance to sample a reference signal in the sampling phase and to hold the sampled reference signal in the amplifying phase, and
a plurality of switches, each switching between the sampling phase and the amplifying phase.

10. The amplifying circuit according to claim 7, further comprising:
a feedback capacitance connected between the input terminal and the output terminal of the operational amplifier.

11. The amplifying circuit according to claim 10 configured to have a differential structure.

12. An analog-to-digital (A-D) converter including the amplifying circuit according to claim 1.

13. An integrated circuit including the A-D converter according to claim 12.

14. A radio communication apparatus including the integrated circuit according to claim 13.
